(19) United States
(12) Patent Application Publication
(10) Pub. No.: US 2026/0201228 A1
(43) Pub. Date: Jul. 16, 2026

(54) COMPOSITION AND METHOD FOR CMP OF METAL FILMS

(71) Applicant: VERSUM MATERIALS US, LLC, Tempe, AZ (US)

(72) Inventors: Mingshih Tsai, New Taipei City (TW); Hongjun Zhou, Chandler, AZ (US); Anupama Mallikarjunan, Koenigstein im Taunus (DE); Rung-Je Yang, Hsinchu City 300 (TW); Matthias Stender, Phoenix, AZ (US); Sana Ma, Phoenix, AZ (US)

(21) Appl. No.: 19/139,273

(22) PCT Filed: Dec. 6, 2023
(86) PCT No.: PCT/US2023/082704

§ 371 Date: Jun. 13, 2025

Related U.S. Application Data
(60) Provisional application No. 63/387,812, filed on Dec. 16, 2022.

(51) Int. Cl. C09K 3/14; B24B 37/20; H10P 52/40; H10P 72/00

(52) U.S. Cl. CPC C09K 3/1463; B24B 37/20; H10P 52/403; H10P 72/0428

(57) ABSTRACT

A chemical mechanical planarization composition for polishing molybdenum comprising a water based liquid carrier; abrasive particles dispersed in the liquid carrier; an amine compound with an acid group selected from the group consisting of carboxylic acid, phosphoric acid and sulfonic acid; and an oxidizer selected from the group of hydrogen peroxide, ferric nitrate, potassium iodate, and mixtures thereof. A method for chemical mechanical polishing a substrate including a molybdenum layer includes contacting the substrate with the above described polishing composition; moving the polishing composition relative to the substrate; and abrading the substrate to remove a portion of the molybdenum layer from the substrate.

### RELATED APPLICATIONS

This application claims priority to U.S. Provisional Patent application No. 63/387,812 filed on Dec. 16, 2022, which is hereby incorporated by reference.

### BACKGROUND

The disclosed embodiments related to chemical mechanical polishing of metal layers and more particularly related to compositions and methods for polishing metal layers comprising molybdenum.

Chemical mechanical polishing compositions employ an oxidizer such as hydrogen peroxide that can be chemically aggressive to the polished metal. In the advanced node of IC manufacturing, molybdenum is one of promising metals to replace tungsten as the conductive contacts to silicon devices to form the integrated circuit. There is a CMP slurry and process needed to polish molybdenum while not lead to corresponding corrosions.

### BRIEF SUMMARY

A chemical mechanical polishing composition for polishing a substrate having a molybdenum layer is disclosed. The polishing composition comprises, consists essentially of, or consists of a water based liquid carrier, abrasive particles dispersed in the liquid carrier, an amine compound with an acid group, an oxidizer.

A method for chemical mechanical polishing a substrate including a molybdenum layer is further disclosed. The method may include contacting the substrate with the above described polishing composition, moving the polishing composition relative to the substrate, and abrading the substrate to remove a portion of the molybdenum layer from the substrate and thereby polish the substrate.

The pH of the CMP composition ranges from 2.0 to 6.0, preferably 2.1 to 3.5 and the CMP composition is a stable composition.

The suitable abrasives include but are not limited to alumina, ceria, colloidal silica, high purity colloidal silica having <1 ppm trace metal, titania, zirconia, a metal-modified or composite particles abrasive, such as iron-coated silica, silica-coated alumina, and combinations thereof. Colloidal silica and high purity colloidal silica particles are preferred.

The abrasive particles have a mean particle size ranging from 20 nm to 180 nm; 30 nm to 150 nm, 35 to 80 nm, or 40 to 75 nm.

The concentrations of abrasive range from 0.1 wt. % to 20 wt. %, preferably from 0.1 wt. % to 10 wt. %, more preferably from 0.1 wt. % to 5 wt. %, and most preferably from 0.1 wt. % to 3 wt. %; which are selected for tuning film removal rates, especially tuning dielectric film removal rates.

Suitable oxidizing agents include hydrogen peroxides, potassium iodates, ferric nitrate, and combinations thereof; and the oxidizing agent ranges from 1 ppm and 100000 ppm.

Hydrogen peroxide (H2O2) or potassium iodate is a preferred oxidizing agent. In some embodiments, the oxidizing agents are hydrogen peroxide, potassium iodate and ferric nitrate.

The oxidizer is typically present in an amount between 1 ppm and 100000 ppm, preferably between 100 ppm to 50000 ppm, and more preferably between 5000 ppm to 35000 ppm by weight.

The corrosion inhibitor for Mo ranging between 0.01% to 10%, preferably between 0.1% to 0.5%, and most preferably between 0.1% to 0.3% by weight;

Inorganic acids, such as nitric acid, sulfonic acid, or phosphoric acid is used as pH adjusting agent, and inorganic base, such as ammonia hydroxide, potassium hydroxide or sodium hydroxide is also used as pH adjust agent.

Suitable biocides include but are not limited to Kathon™, Kathon™ CG/ICP II, from Dow Chemical Co. They have active ingredients of 5-chloro-2-methyl-4-isothiazolin-3-one and 2-methyl-4-isothiazolin-3-one.

Biocides are used in a range from 0.0001 wt. % to 0.05 wt. %; preferably from 0.0005 wt. % to 0.025 wt. %, and more preferably from 0.001 wt. % to 0.01 wt. %.

Stabilizers may also be used at low pH. Stabilizers are optional. Stabilizers include but are not limited to organic carboxylic acids or organic carboxylic acid salts. These stabilizers include, but not limited to, malonic acid, citric acid, tartaric acid, lactic acid, oxalic acid, ascorbic acid, acetic acid, gluconic acid, and their sodium salts, potassium salts and ammonium salts.

Stabilizers can be used in the range of 250 ppm to 10000 ppm, and more preferred range of 400 ppm to 5000 ppm (or 0.04 wt. % to 0.5 wt. %).

In another embodiment, a method of chemical mechanical polishing of a substrate comprising molybdenum is provided, said method comprising: movably contacting a surface of the substrate with a) an abrasive, and b) a liquid component comprising: water; an acid, preferably a mineral acid or base, sufficient to provide a pH of 2 to 6, for example between 2.1 and 3.5; an oxidizer ranges between 1 ppm and 100000 ppm, preferably between 100 ppm to 50000 ppm, and more preferably between 5000 ppm to 35000 ppm by weight; wherein in a preferred embodiment the liquid component is deionized wafer, and wherein the static etch rate less than 100 angstroms per minute (“Å/min”) of molybdenum.

In another aspect, a method is provided for chemical mechanical polishing of a substrate comprising molybdenum; dielectric layer such as silicon oxide or silicon nitride; and barrier films, such as TiN or Ti.

The method of chemical mechanical polishing a semiconductor substrate containing a surface comprising molybdenum and at least one of dielectric layer or barrier layer, comprising steps of: providing the semiconductor substrate; providing a polishing pad; providing the chemical mechanical polishing (CMP) compositions disclosed above; contacting the surface of the semiconductor substrate with the polishing pad and the chemical mechanical polishing composition; and polishing the surface of the semiconductor; wherein the dielectric layer is a silicon oxide or silicon nitride film and the barrier layer is selected from the group consisting of TIN, Ti, TaN, Ta and combinations thereof.

The removal rate for molybdenum is greater than 1300, 1500, 2000 Å/min, or 2500 Å/min; removal rate for the dielectric layer is between 15 to 200 Å/min; removal rate for the barrier layer is between 30 to 500 Å/min.

In one embodiment, the method comprises movably contacting a surface having molybdenum thereon with a) an abrasive suspended in a liquid to form a slurry, said slurry comprising: between 0.1 and 20% by weight, for example between 0.5 and 5% by weight of said abrasive; said liquid comprising water; an acid or a base sufficient to provide a pH of 2 to 6; of an oxidizer ranges from 1 ppm and 100000 ppm, preferably between 100 ppm to 50000 ppm, and more preferably between 5000 ppm to 35000 ppm by weight; and between 0.01 to 1000 ppm, preferably between 0.1 to 100 ppm, and more preferably between 0.5 to 10 ppm by weight; and most preferably between 1 to 5 ppm by weight; said liquid being substantially free of fluoride-containing compounds, wherein the polishing removes greater than 1000 angstroms per minute (Å/min) of molybdenum and varied thickness of oxide films.

### BRIEF DESCRIPTION OF SEVERAL VIEWS OF THE DRAWINGS

The accompanying drawings, which are included to provide a further understanding of the disclosed subject matter and are incorporated in and constitute a part of this specification, illustrate embodiments of the disclosed subject matter and together with the description serve to explain the principles of the disclosed subject matter. In the drawings:

FIG. 1 illustrates static etch rate of molybdenum at 50° C. vs. molybdenum removal rate for different oxidizers.

### DETAILED DESCRIPTION

This disclosure involves is on the Mo CMP bulk polishing compositions and systems used for chemical mechanical polishing of a substrate comprising molybdenum, silicon oxide (such as TEOS, PETEOS) or silicon nitride, and barrier films such as TIN, Ti, TaN, or Ta.

The Mo CMP polishing composition comprises: an abrasive; a solvent selected from the group consisting of water, liquid which is miscible with water, and combinations thereof; an amine compound with a carboxylic acid, or a phosphoric acid, or a sulfonic acid; an oxidizing agent; pH adjusting agent; a biocide; wherein pH of the CMP composition ranges are from 2.0 to 6.0, preferably 2.1 to 3.5.

The abrasive includes but is not limited to alumina, ceria, colloidal silica, high purity colloidal silica having trace metal level <1 ppm, titania, zirconia and combinations thereof.

Colloidal silica and high purity colloidal silica particles are preferred.

The abrasive particles have any shape, such as spherical or cocoon shapes.

The high purity colloidal silica (due to the high purity) are prepared from TEOS or TMOS, such high purity colloidal silica particles have very low trace metal levels, typically in the ppb levels or very low ppm level, such as <1 ppm).

Abrasive particle shapes are measured by TEM or SEM methods. The mean abrasive sizes or particle size distribution can be measured by using any suitable techniques, such as disk centrifuge (DC) method, or dynamic light scattering (DLS), colloidal dynamic method, or by Malvern Size Analyzer.

The abrasive particles have a mean particle size ranging from 20 nm to 180 nm; 30 nm to 150 nm, 35 to 80 nm, or 40 to 75 nm.

The CMP composition can use two or more different abrasives having different sizes.

The concentrations of abrasive range from 0.1 wt. % to 20 wt. %, preferably from 0.1 wt. % to 10 wt. %, more preferably from 0.1 wt. % to 5 wt. %, and most preferably from 0.1 wt. % to 3 wt. %; which are selected for tuning film removal rates, especially tuning dielectric film removal rates.

In some embodiments, the abrasive particle may comprise a high purity colloidal silica dispersion such as PL-3C (comprising a cation-type, cocoon-shaped silica particle) by Fuso Chemical Co., Ltd. The abrasive particles can be surface modified, and in some embodiments, the abrasive particles are cation-type or anionic-type. The abrasives can be, PL-1, PL-1M, PL-2, PL-2C, PL-3, PL-7, PL-2D by Fuso Chemical Co. Ltd.

The oxidizer is typically present in an amount between 1 ppm and 100000 ppm, preferably between 100 ppm to 50000 ppm, and more preferably between 5000 ppm to 35000 ppm by weight.

One problem with aggressive molybdenum slurries is that the chemistry can attack molybdenum during for example idle periods when there is no polishing, that is, no movement of abrasives sufficient to remove the oxide coating formed by the oxidizing system.

The corrosion inhibitor for Mo ranging between 0.01 to 1000 ppm, preferably between 0.1 to 100 ppm, and more preferably between 0.5 to 10 ppm by weight; and most preferably between 1 to 5 ppm by weight.

Inorganic acids, such as nitric acid, sulfonic acid, or phosphoric acid is used as pH adjusting agent, and inorganic base, such as ammonia hydroxide, potassium hydroxide or sodium hydroxide is also used as pH adjust agent.

The choice of acid or base is not limited provided that the strength of the acid or base is sufficient to afford a desired pH in the range of 2-6 for the slurry.

Suitable biocides include but are not limited to Kathon™, Kathon™ CG/ICP II, from Dow Chemical Co. They have active ingredients of 5-chloro-2-methyl-4-isothiazolin-3-one and 2-methyl-4-isothiazolin-3-one.

Biocides are used in a range from 0.0001 wt. % to 0.05 wt. %; preferably from 0.0005 wt. % to 0.025 wt. %, and more preferably from 0.001 wt. % to 0.01 wt. %.

This disclosure provides methods that utilizes the disclosed CMP compositions for chemical mechanical planarization of a molybdenum-containing substrate. Minimization or prevention of dishing/erosion and plug recess of features on semiconductor substrates as well as tunability of selectivity during CMP processing is becoming increasingly more important as the semiconductor industry trends to smaller and smaller feature sizes in the manufacture of integrated circuits.

The solvent which provides the principle portion of the liquid component can be water or mixtures of water with other liquids that are miscible with water. Examples of other liquids are alcohols, such as methanol and ethanol. Advantageously the solvent is water.

The slurry composition used in the method of this disclosure is acidic and has a pH ranging from 2 to 6. Preferably, the pH ranges from 2.1 to 3.5.

The wide pH ranges provide the advantages highly tunable Mo:TEOS selectivity.

Stabilizers may also be used. At low pH, Stabilizers are optional. Stabilizers include but are not limited to organic carboxylic acids or organic carboxylic acid salts. These stabilizers include, but not limited to, malonic acid, citric acid, tartaric acid, lactic acid, oxalic acid, ascorbic acid, acetic acid, gluconic acid, and their sodium salts, potassium salts and ammonium salts.

Stabilizers can be used in the range of 250 ppm to 10000 ppm, and more preferred range of 400 ppm to 5000 ppm (or 0.04 wt. % to 0.5 wt. %).

The method of this disclosure entails use of the afore mentioned CMP compositions (as disclosed supra) for chemical mechanical planarization of substrates comprised of molybdenum, barrier such as TiN or Ti, TaN or Ta; and dielectric materials such as TEOS, PETOES and low-k materials.

The method of chemical mechanical polishing a semiconductor substrate containing a surface comprising molybdenum and at least one of dielectric layer or barrier layer, comprising steps of: providing the semiconductor substrate; providing a polishing pad; providing the chemical mechanical polishing (CMP) compositions disclosed above; contacting the surface of the semiconductor substrate with the polishing pad and the chemical mechanical polishing composition; and polishing the surface of the semiconductor; wherein the dielectric layer is an oxide film and the barrier layer is selected from the group consisting of TIN, Ti, TaN, Ta and combinations thereof.

And in a preferred embodiment the polishing composition is free of fluoride-containing compounds.

In the method, a substrate (e.g., a wafer) is placed face-down toward a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CMP processing while the platen and the substrate are rotated. The polishing composition (slurry) is applied (usually continuously) on the pad during CMP processing to affect the removal of material to planarize the substrate.

In the method of the disclosure with use of the associated slurry, a removal rate of molybdenum of at least greater than 1000 Angstroms per minute and a removal rate of TEOS is ranging from less than 10 Angstroms per minute to greater than 500 Angstroms per minute which are maintained upon chemical-mechanical polishing thereof when polishing is done at 2 psi of down force. Higher removal rates are obtained when down force values are increased.

As indicated above, an embodiment of the disclosure is a composition for chemical mechanical polishing a molybdenum-containing substrate. In an embodiment, the surface of the substrate also has at least one feature thereon comprising a dielectric material, at least near the conclusion of the polishing. In an embodiment, the dielectric material is a silicon oxide.

The removal selectivity of molybdenum over dielectric are between 5 and 500, which depend on the pH and type of abrasives conditions of the invented Mo CMP polishing compositions herein.

The system of this disclosure entails use of the afore mentioned CMP compositions (as disclosed supra) for chemical mechanical planarization of substrates comprised of molybdenum, barrier such as TiN or Ti, TaN or Ta; and dielectric materials such as TEOS, Silicon nitride materials.

In yet another aspect, a system is provided for chemical mechanical polishing of a substrate containing a surface comprising molybdenum and at least one of dielectric layer such as oxide; and barrier films, such as TiN or Ti or TaN or Ta.

The system comprising: a substrate containing a surface comprising molybdenum and at least one of dielectric layer such as oxide; and barrier films, such as TiN or Ti or TaN or Ta; a polishing pad; the chemical mechanical polishing (CMP) compositions disclosed above; and wherein the surface of the semiconductor substrate is in contact with the polishing pad and the chemical mechanical polishing composition.

In each of the above embodiments, the term “ppm” means parts per million by weight of the slurry (liquid plus abrasive), or of the liquid component if there is no abrasive suspended in the liquid.

A growing trend among CMP slurry providers is the lowering of their customers' cost of consumables through product concentration. The practice of providing concentrated slurry is becoming a demand across the CMP industry. The level of concentration, however, must be prudently chosen so as not to jeopardize the stability and shelf-life time of the product.

We have found that even with slurry concentrates that minimize organics, which can exacerbate long term aging effects, slurry concentrates exhibit some effects on aging, especially relating to dishing and to absolute molybdenum removal rates. Note that slurry concentrates are free of oxidizers, which are added when the slurry concentrate is tank mixed with water and oxidizer to form a polishing slurry. It is known to tune slurries by adding various components thereto. The instant disclosure teaches a method of mixing two different slurry concentrates (called for convenience a primary slurry concentrates and a secondary slurry concentrate), wherein the ratio of mixing of the slurry concentrates depends on the long-term age of the primary slurry concentrate, to normalize slurry performance against aging.

The formulations may be shipped in the concentrate form and diluted at the point of use with the addition of water. Component concentrations in a concentrate would be increased as per the dilution factor at point of use. In the illustrated embodiment, the dilution factor is between about 2× and about 10×, preferably between about 3× and about 5×.

### Glossary

### CMP Methodology

In the examples presented below, CMP experiments were run using the procedures and experimental conditions given below.

All percentages are weight percentages unless otherwise indicated.

### Components

Colloidal Silica: first colloidal silica used as abrasive having a mean particle size of approximately 45 nanometers (nm); second colloidal silica used as abrasive having a mean particle size of approximately 70 nanometers (nm);

Col Sil: Colloidal silica particles (with varied sizes) supplied by Fuso Chemical Inc. in Japan.

### Parameters

### General

Å or A: angstrom(s)—a unit of length
BP: back pressure, in psi units
CMP: chemical mechanical planarization=chemical mechanical polishing
CS: carrier speed
DF: Down force: pressure applied during CMP, units psi
min: minute(s)
ml: milliliter(s)
mV: millivolt(s)
psi: pounds per square inch
PS: platen rotational speed of polishing tool, in rpm (revolution(s) per minute)
SF: slurry flow, ml/min
Wt. %: weight percentage (of a listed component)
Mo:SiN Selectivity: (removal rate of Mo)/(removal rate of SiN)
TEOS:Mo Selectivity: (removal rate of TEOS)/(removal rate of Mo)

Molybdenum Removal Rates: Measured molybdenum removal rate at a given down pressure. The down pressure of the CMP tool was 2.0 psi in the examples listed above.

Molybdenum films were measured with a ResMap CDE, model 168, manufactured by Creative Design Engineering, Inc, 20565 Alves Dr., Cupertino, CA, 95014. The ResMap tool is a four-point probe sheet resistance tool. Forty-nine-point diameter scan at 5 mm edge exclusion for Molybdenum film was taken.

### CMP Tool

The CMP tool that was used is a 300 mm Reflexion LK, manufactured by Applied Materials, 3050 Boweres Avenue, Santa Clara, California, 95054. An IC1010 pad supplied by DOW, Inc, 451 Bellevue Rd., Newark, DE 19713 was used for blanket and pattern wafer studies.

The IC1000 or IC1010 pad was broken in by conditioning the pad for 10 mins. At 5 lbs down force on the conditioner.

### WORKING EXAMPLES

The present disclosure further includes the examples provided below.

Polishing experiments were conducted using PVD deposited Molybdenum wafers. These blanket wafers were purchased from Advantiv. The film thickness specifications are summarized below: Mo: 5,000 Å PVD molybdenum.

### Polishing Experiments

In blanket wafer studies, molybdenum blanket wafers, and TEOS blanket wafers were polished at baseline conditions. The tool baseline conditions were: table speed; 93 rpm, head speed: 87 rpm, membrane pressure; 2.0 psi, slurry flow; 300 ml/min.

In the following example formulations, the abrasive particles was Fuso PL-3C at 1.0 wt. %.

It will be understood that the disclosure includes numerous embodiments. These embodiments include, but are not limited to, the following embodiments.

### Example 1

This example demonstrates the effectiveness of amino acids to reduce the static etch rate of molybdenum at elevated temperature 50 C. There were sixteen compositions were prepared (Example 1A, 1B, 1C, 1D, 1E, 1F, 1G, 1H, 1I, 1J, 1K, 1L, 1M, 1N, 1O, 1P). Each composition included 0.08 weight percent malonic acid, and 1.0 weight percent hydrogen peroxide at pH 2.3. The particular amino acid and concentration used in each composition are listed in Table I.

The static etch rate of molybdenum in each of the above-described sixteen compositions was evaluated. Two-inch square coupon wafer having a molybdenum layer were submersed in the respective compositions (molybdenum side up) for one minute at 50 degrees C. Molybdenum removal rates were determined via resistivity measurements made before and after immersion in the compositions.

As is apparent from the results set forth in Table 1, the etch rate of molybdenum was lower in compositions with higher concentration amino acids at 0.5% compared to those at 0.1% concentration. It is evident that the etch rate of molybdenum is lower in compositions including L-Histidine, L-Lysine and L-Arginine compared to those with Glycine, L-Valine, L-Serine. The relative Mo RR with 300 mm wafer polishing is shown in Table I, The highest Mo RR in the composition 1B can reach 988 Å/min, even higher at 1126 Å/min and 1037 Å/min in the composition 1K and 1O.

TABLE I

| | | | | | | TEOS |
|---|---|---|---|---|---|---|
| | | | | Mo SER | Mo RR | RR |
| | Amino | Concentration | H₂O₂ | @ 50°C. | 300 mm | 300 mm |
| Composition | acid | (wt. %) | (wt. %) | (Å/min) | (Å/min) | (Å/min) |
| 1A | NA | | | | NA | |
| 1B | Glycine | 0.1 | 1 | 286.1 | 988 | 61 |
| 1C | Glycine | 0.5 | 1 | 159.5 | 908 | 89 |
| 1D | Histidine | 0.05 | 1 | 127 | 535 | NA |
| 1E | Histidine | 0.1 | 1 | 79.4 | 495 | 56 |
| 1F | Histidine | 0.5 | 1 | 58.2 | 300 | 77 |
| 1G | L-Lysine | 0.1 | 1 | 135.2 | 389 | 57 |
| 1H | L-Lysine | 0.5 | 1 | 75.4 | 262 | 87 |
| 1I | L- | 0.1 | 1 | 88.1 | 372 | 58 |
| | Arginine | | | | | |
| 1J | L- | 0.5 | 1 | 58.9 | 210 | 83 |
| | Arginine | | | | | |
| 1K | L-Valine | 0.1 | 1 | 371.4 | 1126 | 57 |
| 1L | L-Valine | 0.5 | 1 | 203.9 | 987 | 80 |
| 1M | L-Serine | 0.1 | 1 | 272.9 | 919 | 56 |
| 1N | L-Serine | 0.5 | 1 | 143.6 | 746 | 80 |
| 1O | Sarcosine | 0.1 | 1 | 299.2 | 1037 | 57 |
| 1P | Sarcosine | 0.5 | 1 | 193.7 | 884 | 75 |

### Example 2

This example demonstrates the alternative oxidizer, Ferric nitrate at 0.75 wt. %, instead of hydrogen peroxide can effectively reduce the static etch rate of molybdenum at elevated temperature 50C less than 100 Å/min, and in the meanwhile the Mo RRs with coupon wafer polishing can be as higher than 1300 Å/min. There were sixteen compositions were prepared (Example 2A, 2B, 2C, 2D, 2E, 2F, 2G, 2H, 2I, 2J, 2K, 2L, 2M, 2N, 2O). Each composition included 0.08 weight percent malonic acid, and 1.0 weight percent hydrogen peroxide at pH 2.3. The particular amino acid and concentration used in each composition are listed in Table II.

TABLE II

| | | | | | | Mo RR |
|---|---|---|---|---|---|---|
| | | | | Ferric | Mo SER @ | 4 × 4 cm² |
| | Amino | Concentration | H₂O₂ | Nitrate | 50° C. | coupon |
| Composition | acid | (wt. %) | (wt. %) | (wt. %) | (Å/min) | (Å/min) |
| 2A | Glycine | 0.1 | 1.0 | — | 310.0 | 743 |
| 2B | Glycine | 0.10 | — | 0.75 | 88.6 | 1984 |
| 2C | Glycine | 0.30 | — | 0.75 | 93.3 | 2218 |
| 2D | Histidine | 0.10 | — | 0.75 | 71.2 | 1736 |
| 2E | Histidine | 0.30 | — | 0.75 | 55.1 | 1364 |
| 2F | L-Lysine | 0.10 | — | 0.75 | 71.5 | 1844 |
| 2G | L-Lysine | 0.30 | — | 0.75 | 60.2 | 1501 |
| 2H | L-Arginine | 0.10 | — | 0.75 | 70.4 | 1357 |
| 2I | L-Arginine | 0.30 | — | 0.75 | 59.6 | 1536 |
| 2J | L-Valine | 0.10 | — | 0.75 | 76.2 | 1991 |
| 2K | L-Valine | 0.30 | — | 0.75 | 80.1 | 1992 |
| 2L | L-Serine | 0.10 | — | 0.75 | 81.6 | 2124 |
| 2M | L-Serine | 0.30 | — | 0.75 | 80.2 | 2080 |
| 2N | Sarcosine | 0.10 | — | 0.75 | 73.3 | 2018 |
| 2O | Sarcosine | 0.30 | — | 0.75 | 85.6 | 2009 |

### Example 3

This example demonstrates the amine compounds with phosphoric acid, namely 2-aminoethyl phosphoric acid and 3-aminopropyl phosphonic acid, and sulfonic acids, namely 3-amino-1-propanesulfonic acid and aminomethanesulfonic acid. There were nine compositions were prepared (Example 3A, 3B, 3C, 3D, 3E, 3F, 3G, 3H, 3I) Each composition included 0.08 weight percent malonic acid, and 1.0 weight percent hydrogen peroxide at pH 2.3. The particular amino acid and concentration used in each composition are listed in Table III. the static etch rate of molybdenum at elevated temperature 50C, can be reduced less than 100 Å/min for those with amino-phosphoric acid as concentration higher than 0.35% and 0.5% for example 3C and 3E respectively. the Mo static etch rates of amino-sulphonic acids, example 3G and 3I, were not profoundly reduced like amino-phosphoric acids, but still lower than the control example 3A as shown in Table III.

TABLE III

| | | | | Mo SER |
|---|---|---|---|---|
| | | Concentration | H₂O₂ | @ 50° C. |
| Composition | Amino acid | (wt. %) | (wt. %) | (Å/min) |
| 3A | none | — | 1.00 | 555.0 |
| 3B | 2-aminoethyl phosphoric acid | 0.175 | 1.00 | 140.3 |
| 3C | 2-aminoethyl phosphoric acid | 0.35 | 1.00 | 90.4 |
| 3D | 3-aminopropyl phosphonic acid | 0.1 | 1.00 | 188.4 |
| 3E | 3-aminopropyl phosphonic acid | 0.5 | 1.00 | 97.7 |
| 3F | 3-Amino-1-propanesulfonic acid | 0.175 | 1.00 | 475.5 |
| 3G | 3-Amino-1-propanesulfonic acid | 0.35 | 1.00 | 382.2 |
| 3H | Aminomethane sulfonic acid | 0.175 | 1.00 | 941.7 |
| 3I | Aminomethane sulfonic acid | 0.35 | 1.00 | 510.0 |

### Example 4

This example demonstrates the combination of various types of amino acids, glycine and L-histidine, and oxidizers, hydrogen peroxide, potassium iodate and ferric nitrate for both Mo static etch rates and 300 mm Mo removal rates. There were twelve compositions were prepared (Example 4A, 4B, 4C, 4D, 4E, 4F, 4G, 4H, 4I, 4J, 4K) Each composition included 0.08 weight percent malonic acid, and 1.0 weight percent hydrogen peroxide at pH 2.3. The particular amino acid, oxidizer and their relative concentrations used in each composition are listed in Table IV. The Mo static etch rate at 50 C can be significantly reduced less than 50 Å/min and Mo removal rate were higher than 800 Å/min for the composition 4F and 4G with potassium iodate as the oxidizer. even lower Mo static etch rates for the composition 4H and 4J with ferric nitrate as the oxidizer, although relatively lower Mo removal rates around 690 to 650 Å/min respectively.

TABLE IV

| | | | | | | Mo SER @ | Mo RR |
|---|---|---|---|---|---|---|---|
| | Amino | Concentration | H₂O₂ | KIO₃ | Fe(NO₃)₃ | 50° C. | 300 mm |
| Composition | acid | (wt. %) | (wt. %) | (wt. %) | (wt. %) | (Å/min) | (Å/min) |
| 4A | Glycine | 0.10 | 1.00 | | | 344.3 | 1120 |
| 4B | none | — | | 0.10 | — | 159.8 | 1063 |
| 4C | none | — | | 0.20 | — | 296.9 | 1541 |
| 4D | Glycine | 0.10 | | 0.10 | — | 128.1 | 1139 |
| 4E | Glycine | 0.10 | | 0.20 | — | 270.0 | 1521 |
| 4F | L-Histidine | 0.10 | | 0.10 | — | 21.3 | 821 |
| 4G | L-Histidine | 0.10 | | 0.20 | — | 34.2 | 998 |
| 4H | Glycine | 0.10 | | — | 0.10 | 14.2 | 248 |
| 4I | Glycine | 0.10 | | — | 0.30 | 33.3 | 691 |
| 4J | L-Histidine | 0.10 | | — | 0.10 | 9.4 | 255 |
| 4K | L-Histidine | 0.10 | | — | 0.30 | 21.5 | 656 |

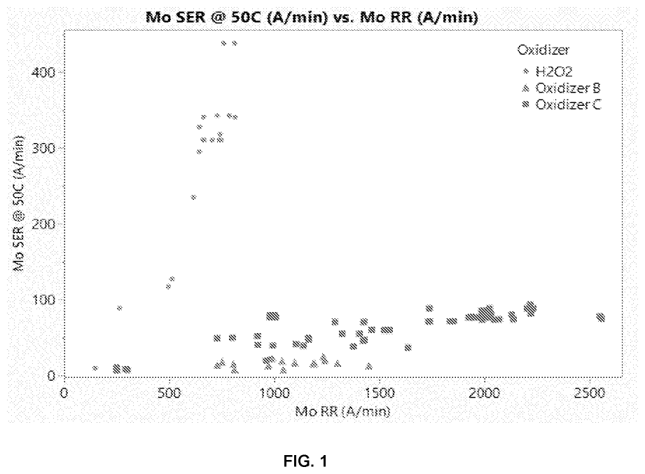

FIG. 1 illustrates static etch rate of molybdenum at 50° C. vs. molybdenum removal rate for different oxidizers: (1) H2O2, (2) Oxidizer B: KIO3, and (3) Oxidizer C: Fe(NO3)3. Of the three oxidizers used in the presently disclosed compositions (1A-4K), H2O2-based formulations, broadly, resulted in higher static etch rates of Mo at 50° C. Broadly, KIO3-based formulations, resulted in lower static etch rates and higher Mo removal rates than H2O2-based formulations. Broadly, Fe(NO3)3-based formulations resulted in lower static etch rates than H2O2-based formulations and higher Mo removal rates than H2O2-based formulations and KIO3-based formulations.

In some embodiments, the RR of Mo is between about 500 and about 2000 Å/min. In some embodiments, the RR of SiN is between about 1 and about 50 Å/min. In some embodiments a removal rate selectivity of Mo to SiN is between about 500:1 and about 5:1, more preferably between about 400:1 and about 10:1

In some embodiments, the RR of TEOS is between about 50 and about 400 Å/min. In some embodiments a removal rate selectivity of Mo to TEOS is between about 1:1 and about 50:1, more preferably between about 1:1 and about 10:1

In some embodiments, the chemical mechanical polishing composition does not contain an anionic polymer or an anionic surfactant

In some embodiments, the chemical mechanical polishing composition contains a cationic surfactant. In an illustrated embodiment, the cationic surfactant is JEFFAMINE® T-403 (Polyetheramine). JEFFAMINE® T-403 (CAS Number 39423-51-3) is characterized by repeating oxypropylene units in the backbone. JEFFAMINE T-403 is a trifunctional primary amine having an average molecular weight of approximately 440. Its amine groups are located on secondary carbon atoms at the ends of aliphatic polyether chains.

In a first embodiment a composition may comprise, consist of, or consist essentially of a chemical mechanical polishing composition comprising: a water based liquid carrier; abrasive particles dispersed in the liquid carrier; an amine compound with an acid group, an oxidizer;

A second embodiment may include the first embodiment wherein the oxidizer is selected from hydrogen peroxide, monohydrate ferric nitrate, and potassium iodate oxidizer, and mixtures thereof.

In an illustrated embodiment the second chemical additive comprises potassium iodate and a third chemical additive comprises malonic acid.

A third embodiment may include any one of the first and second embodiments, wherein the composition further comprising a carboxylic acid which complexes with ferric ions as a stabilizer.

A fourth embodiment may include any one of the first through third embodiments, wherein the amine compound is selected from the group consisting of carboxylic acids, phosphoric acids and sulfonic acids.

A fifth embodiment may include any one of the first through fourth embodiments, wherein the amine compound comprises one or more amino acid from the group consisting of alpha-amino acids, glycine, L-histidine, L-lysine, L-arginine, beta-amino acids, beta-alanine, and mixtures thereof. In an illustrated embodiment the first chemical additive comprises L-histidine and glycine. In a further embodiment, the first chemical additive is L-histidine and the second chemical additive is KIO3.

A sixth embodiment may include any one of the first through fifth embodiments, wherein the amine compound is an amino phosphoric acid is selected from the group consisting of (aminomethyl)phosphoric acid, (2-aminoethyl)phosphoric acid, and (3-aminoethyl)phosphoric acid, and mixtures thereof.

A seventh embodiment may include any one of the first through sixth embodiments, wherein the amine compound is the amino sulfonic acid is selected from the group consisting of aminomethansulfonic acid, 2-aminoethanesulfonic acid, 3-amino-1-propansulfonic acid, and mixtures thereof.

An eighth embodiment may include any one of the first through seventh embodiments, wherein the abrasive particles comprise cationic or anionic silica, zirconia and alumina.

In a nineth embodiment a method of chemical mechanical polishing a substrate having a molybdenum layer may comprise, consist of, or consist essentially of (a) contacting the substrate with any one of the first through eighth polishing composition embodiments; (b) moving the polishing composition relative to the substrate; and (c) abrading the substrate to remove a portion of the molybdenum layer or the molybdenum layer from the substrate and thereby polish the substrate.

The embodiments listed above, including the working example, are exemplary of numerous embodiments that may be made of this disclosure. It is contemplated that numerous other configurations of the process may be used, and the materials used in the process may be elected from numerous materials other than those specifically disclosed.

1. A chemical mechanical polishing composition comprising:
0.1 wt. % to 20 wt. %, preferably from 0.1 wt. % to 10 wt. %, more preferably from 0.1 wt. % to 5 wt. %, and most preferably from 0.1 wt. % to 3 wt. % of abrasive particles;
0.01 wt. % to 10.0% wt. %, preferably 0.1 wt. % to 8.0 wt. %, or most preferably 1 wt. % to 5 wt. % of a first chemical additive, wherein the first chemical additive comprises an amine compound, the amine compound further comprising a carboxylic acid, or a phosphoric acid, or a sulfonic acid;
between 0.01 and 0.2 wt. % or preferably between 0.01 and 0.05 wt. % of a second chemical additive, wherein the second chemical additive is an oxidizer selected from a group consisting of: hydrogen peroxide, ferric nitrate, potassium iodate, and mixtures thereof;
a water soluble solvent; and optionally
biocide; and pH
adjuster;
wherein the chemical mechanical polishing composition has a pH of 2 to 7, preferably 2 to 5, more preferably 2 to 4, and most preferably 2 to 3.5.

2. The chemical mechanical polishing composition of claim 1, wherein the abrasive particles are selected from alumina, ceria, colloidal silica, high purity colloidal silica having <1 ppm trace metal, titania, zirconia, a metal-modified or composite particles abrasive, such as iron-coated silica, silica-coated alumina, and combinations thereof.

3. The chemical mechanical polishing composition of claim 1, wherein the amine compound comprises one or more amino acids selected from the group consisting of alpha-amino acids, glycine, L-histidine, L-lysine, L-arginine, beta-amino acids, beta-alanine, and mixtures thereof.

4. The chemical mechanical polishing composition of claim 1, wherein the amine compound is an amino phosphoric acid is selected from the group consisting of (aminomethyl)phosphoric acid, (2-aminoethyl)phosphoric acid, and (3-aminoethyl)phosphoric acid, and mixtures thereof.

5. The chemical mechanical polishing composition of claim 1, wherein the amine compound is the amino sulfonic acid is selected from the group consisting of aminomethansulfonic acid, 2-aminoethanesulfonic acid, 3-amino-1-propansulfonic acid, and mixtures thereof.

6. The chemical mechanical polishing composition of claim 1, wherein the oxidizer is ferric nitrate or potassium iodate.

7. The chemical mechanical polishing composition of claim 1, wherein static etch rate of molybdenum at 50 degrees Celsius is less than 100 A/min, more preferably less than 50 A/min.

8. The chemical mechanical polishing composition of claim 1, the abrasive particles comprises surface-modified colloidal silica, preferably cationic colloidal silica or anionic colloidal silica.

9. The chemical mechanical polishing composition of claim 1, wherein the chemical mechanical polishing composition contains a cationic surfactant; or
wherein the chemical mechanical polishing composition does not contain an anionic polymer or an anionic surfactant.

10. A chemical mechanical polishing composition comprising:
0.1 wt. % to 10 wt. %, preferably from 0.1 wt. % to 5 wt. %, more preferably from 0.1 wt. % to 3 wt. %, and most preferably from 0.5 wt. % to 2 wt. % of abrasive particles;
0.01 wt. % to 10.0% wt. %, preferably 0.05 wt. % to 5.0 wt. %, or most preferably 0.1 wt. % to 1 wt. % of a first chemical additive, wherein the first chemical additive comprises an amine compound, the amine compound further comprising a carboxylic acid, or a phosphoric acid, or a sulfonic acid;
between 0.01 and 0.0 wt. % or preferably between 0.01 and 0.5 wt. % of a second chemical additive, wherein the second chemical additive is an oxidizer selected from a group consisting of: ferric nitrate, potassium iodate, and mixtures thereof;
a water soluble solvent; and optionally
biocide; and pH
adjuster;
wherein the chemical mechanical polishing composition has a pH of 2 to 7, preferably 2 to 5, more preferably 2 to 4, and most preferably 2 to 3.5; and
wherein the chemical mechanical polishing composition does not contain hydrogen peroxide.

11. The chemical mechanical polishing composition of claim 10, wherein the amine compound comprises one or more amino acids selected from the group consisting of alpha-amino acids, glycine, L-histidine, L-lysine, L-arginine, beta-amino acids, beta-alanine, and mixtures thereof.

12. The chemical mechanical polishing composition of claim 10, wherein the amine compound is an amino phosphoric acid is selected from the group consisting of (aminomethyl)phosphoric acid, (2-aminoethyl)phosphoric acid, and (3-aminoethyl)phosphoric acid, and mixtures thereof.

13. The chemical mechanical polishing composition of claim 10, wherein the amine compound is the amino sulfonic acid is selected from the group consisting of Aminomethansulfonic acid, 2-aminoethanesulfonic acid, 3-amino-1-propansulfonic acid, and mixtures thereof.

14. The chemical mechanical polishing composition of claim 10, wherein a ratio of the first chemical additive to the second chemical additive is between about 10:1 and about 1:10, preferably between about 3:1 and about 1:3, and most preferably about 2:1 to about 1:2.

15. The chemical mechanical polishing composition of claim 1, wherein a static etch rate of molybdenum at 50 degrees Celsius is less than 200 A/min, preferably less than 100 A/min, and more preferably less than 75 A/min.

16. A method of chemical mechanical polishing (CMP) a semiconductor substrate having at least one surface comprising a film containing molybdenum, comprising:
providing the semiconductor substrate; providing a
polishing pad;
providing the chemical mechanical polishing (CMP) composition in claim 1;
contacting the surface of the semiconductor substrate with the polishing pad and the chemical mechanical polishing composition; and
polishing the least one surface.

17. The method of claim 16, wherein the semiconductor substrate further comprises a silicon oxide film, and wherein the silicon oxide film is selected from the group consisting of Chemical vapor deposition (CVD), Plasma Enhance CVD (PECVD), High Density Deposition CVD (HDP), or spin on silicon oxide film.

18. The method of claim 17, wherein the silicon oxide film is SiO2 film and removal selectivity of molybdenum:silicon oxide is greater than 10, preferably greater than 30, and more preferably greater than 50.

19. The method of claim 16, wherein a removal rate selectivity of Mo to SiN is between about 500:1 and about 5:1; or
wherein a removal selectivity of molybdenum:silicon oxide is greater than 5, preferably greater than 50, and more preferably greater than 500.

20. A system of chemical mechanical polishing (CMP) a semiconductor substrate having at least one surface comprising a film containing molybdenum, comprising:
a. the semiconductor substrate;
b. the chemical mechanical polishing (CMP) composition of claim 1; and
c. a polishing pad;
wherein the at least one surface comprising molybdenum is in contact with the polishing pad and the chemical mechanical polishing composition.
